(19) United States
(12) Patent Application Publication
(10) Pub. No.: US 2022/0320186 A1
(43) Pub. Date: Oct. 6, 2022

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Ge WANG, Beijing (CN); Ping WEN, Beijing (CN); Zhiliang JIANG, Beijing (CN); Jiang XIE, Beijing (CN); Yu WANG, Beijing (CN); Yang ZENG, Beijing (CN)

(21) Appl. No.: 17/638,594

(22) PCT Filed: Jan. 7, 2021
(86) PCT No.: PCT/CN2021/070661

§ 371 Date: Feb. 25, 2022

(30) Foreign Application Priority Data
Jan. 10, 2020 (CN) 202010026172.1

(51) Int. Cl. H01L 27/32; H01L 51/52; G02B 5/30

(52) U.S. Cl. CPC H01L 27/323; H01L 51/5293; G02B 5/3083

(57) ABSTRACT

A display panel and a display device, relating to the field of display technology. The display panel comprises: an OLED display substrate, a touch substrate and a linear polarizer which are stacked in sequence; the touch substrate comprises a touch substrate layer and a touch electrode provided on the touch substrate layer, and the touch substrate layer is configured as a phase delay layer, and cooperates with the linear polarizer to reduce the reflection effect of the display panel on ambient light. Compared with a conventional OLED display panel, the OLED display panel has a lower cost, a thinner thickness, a lower reflectivity, a higher contrast, and a better integrated black effect.

### CROSS REFERENCE TO RELATED APPLICATIONS

The present disclosure claims priority of Chinese Patent Application No.

202010026172.1, filed with the China National Intellectual Property Administration (CNIPA) on Jan. 10, 2020, and entitled “DISPLAY PANEL AND DISPLAY DEVICE”, the entire content of which is incorporated herein by reference.

### FIELD

The present disclosure relates to the technical field of display, in particular to a display panel and a display device.

### BACKGROUND

An Organic Light Emitting Diode (OLED) display has a self-luminous property, and theoretically does not need to use two linear polarizers to control the direction of light like an LCD display. However, since a cathode in the OLED display and a metal wire on a TFT substrate of the OLED display have a strong reflection effect, the contrast of the OLED display under strong ambient light is reduced, which affects the use of the display. Therefore, in the current OLED display manufacturing process, a circular polarizer is mostly used to eliminate reflected light. The circular polarizer is generally composed by laminating a plurality of layers of films and has a large thickness, which is a major obstacle to the thinning of the current OLED displays.

### SUMMARY

Embodiments of the present disclosure provide a display panel, including:

an OLED display substrate;

a touch substrate, located on a display surface of the OLED display substrate, and comprising: a touch substrate layer configured as a phase delay layer; and a touch electrode on a side, facing away from the OLED display substrate, of the touch substrate layer; and

a linear polarizer, on a side, away from the OLED display substrate, of the touch substrate.

The linear polarizer cooperates with the touch substrate layer to reduce a reflection effect of the display panel on ambient light.

Optionally, in the display panel provided by embodiments of the present disclosure, the touch substrate layer is a ¼λ phase delay layer, and an included angle between a phase difference axis of the ¼λ phase delay layer and a transmission axis of the linear polarizer is 40 degrees to 50 degrees.

Optionally, in the display panel provided by embodiments of the present disclosure, the included angle between the phase difference axis of the ¼λ phase delay layer and the transmission axis of the linear polarizer is 45 degrees.

Optionally, in the display panel provided by th embodiments of the present disclosure, the touch substrate layer includes a ½λ phase delay layer and a ¼λ phase delay layer, the ½k phase delay layer is close to the linear polarizer, and the ¼λ phase delay layer is away from the linear polarizer.

An included angle between a phase difference axis of the ½λ phase delay layer and a transmission axis of the linear polarizer is 10 degrees to 20 degrees.

An included angle between a phase difference axis of the ¼λ phase delay layer and the transmission axis of the linear polarizer is 70 degrees to 80 degrees.

Optionally, in the display panel provided by embodiments of the present disclosure, the included angle between the phase difference axis of the ¼λ phase delay layer and the transmission axis of the linear polarizer is 15 degrees.

The included angle between the phase difference axis of the ¼λ phase delay layer and the transmission axis of the linear polarizer is 75 degrees.

Optionally, in the display panel provided by embodiments of the present disclosure, the ½λ phase delay layer and the ¼λ phase delay layer are made of the same material, or the ½λ phase delay layer and the ¼λ phase delay layer are made of different materials.

Optionally, in the display panel provided by embodiments of the present disclosure, a material of the touch substrate layer includes one or more of cycloolefin copolymer, polyethylene terephthalate or polycarbonate.

Optionally, in the display panel provided by embodiments of the present disclosure, a phase difference value of the ¼λ phase delay layer is 110 nm-165 nm.

Optionally, in the display panel provided by embodiments of the present disclosure, a phase difference value of the ½λ phase delay layer is 220 nm-330 nm.

In another aspect, embodiments of the present disclosure further provide a display device, including the display panel as described by any one of the above.

### BRIEF DESCRIPTION OF THE DRAWINGS

FIG. 1 is a sectional view chart of a display panel provided by an embodiment of the present disclosure.

FIG. 2 is a sectional view chart of another display panel provided by an embodiment of the present disclosure.

### DETAILED DESCRIPTION OF THE EMBODIMENTS

The technical solutions in the embodiments of the present disclosure will be clearly and completely described below in conjunction with the drawings in the embodiments of the present disclosure. Obviously, the described embodiments are only a part of the embodiments of the present disclosure, but not all of the embodiments. Based on the embodiments in the present disclosure, all other embodiments acquired by those of ordinary skill in the art without creative work shall fall within the protection scope of the present disclosure.

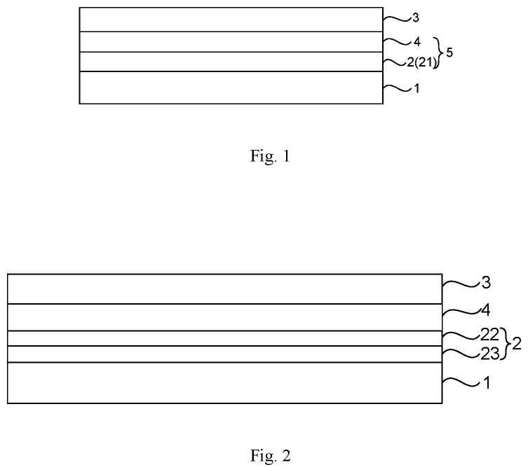

As shown in FIG. 1 and FIG. 2, a display panel provided by embodiments of the present disclosure, includes: an OLED display substrate 1, a touch substrate 5 and a linear polarizer 3 which are stacked in sequence. The touch substrate 5 includes: a touch substrate layer 2, and a touch electrode 4 on the touch substrate layer 2. The touch substrate layer 2 is configured as a phase delay layer, and cooperates with the linear polarizer 3 to reduce the reflection effect of the display panel on ambient light.

The display panel provided by the embodiments of the present disclosure is an OLED display panel, and includes the touch substrate 5. In the touch substrate 5, the touch substrate layer 2 is configured as the phase delay layer. The phase delay layer cooperating with the linear polarizer 3, which can achieve a function of a circular polarizer, has an anti-reflection effect, and can reduce the reflectivity of the display panel on the ambient light and improve the contrast of the display panel. Moreover, compared with the related art using a circular polarizer anti-reflection solution, the display panel provided by the embodiments of the present disclosure only needs to use a common linear polarizer 3. The cost of the linear polarizer is only one-fifth to one-tenth of the cost of the circular polarizer, which can reduce the cost of the display panel. Because there is no phase difference layer in the linear polarizer 3, a thickness is greatly reduced compared with the circular polarizer. Therefore, an overall thickness of the OLED display panel can be effectively reduced, which is conductive to the thinning of the OLED display panel.

In addition, in the related art using the circular polarizer anti-reflection solution, since the touch substrate layer itself has a certain phase difference value, which has a certain interference effect on a phase difference film in the circular polarizer. When the phase difference between the touch substrate layer and the phase difference film is canceled, the actual phase difference value will be reduced, the absorption of a red light part is weakened, the absorption of a blue light part is enhanced, and consequently, the OLED display panel becomes red. When the phase difference between the touch substrate layer and the phase difference film is increased, the actual phase difference value will be increased, the absorption of the blue light part is weakened, the absorption of the red light part is enhanced, and consequently, the OLED display panel becomes blue. Both of the above conditions will lead to increased reflectivity and reduced contrast of the OLED display panel. In contrast, in the embodiments of the present disclosure, the touch substrate layer 2 is adopted directly to cooperate with the linear polarizer 3 to achieve the function of circularly polarized light, and there is no interference problem of the phase difference value of the touch substrate layer 2. Therefore, the display panel can have a better anti-reflection effect, a smaller reflectivity, a higher contrast, and a better integrated black effect.

In conclusion, compared with a conventional OLED display panel, the OLED display panel provided by the embodiments of the present disclosure has the lower cost, the thinner thickness, the lower reflectivity, the higher contrast, and the better integrated black effect.

Optionally, in implementations provided by embodiments of the present disclosure, a material of the touch substrate layer 2 may include one or more of cycloolefin copolymer (COP), polyethylene terephthalate (PET) or polycarbonate (PC).

Optionally, as shown in FIG. 1, in implementations provided by the embodiments of the present disclosure, the touch substrate layer 2 may be of a single layer structure, for example, a ¼λ phase delay layer 21. An included angle between a phase difference axis of the ¼λ phase delay layer 21 and a transmission axis of the linear polarizer 3 is 40 degrees to 50 degrees.

In implementations provided by the embodiments of the present disclosure, the included angle between the phase difference axis of the ¼λ phase delay layer 21 and the transmission axis of the linear polarizer 3 may be 45 degrees. In such a case, the touch substrate layer 2 cooperates with the linear polarizer 3, which can achieve an accurate effect of circularly polarized light, and the anti-reflection effect is the best.

For example, the touch substrate layer may be a ¼λ phase delay layer made of the cycloolefin copolymer (COP) material, or a ¼λ phase delay layer made of the polyethylene terephthalate (PET) material, or a ¼λ phase delay layer made of the polycarbonate (PC) material.

Optionally, as shown in FIG. 2, in other implementations provided by the embodiments of the present disclosure, the touch substrate layer 2 may include two phase delay layers, one of which is a ½λ phase delay layer 22, and the other is a ¼λ phase delay layer 23. The ½λ phase delay layer 22 is close to the linear polarizer 3, and the ¼λ phase delay layer 23 is away from the linear polarizer 3. An included angle between a phase difference axis of the ½λ phase delay layer 22 and a transmission axis of the linear polarizer 3 may be 10 degrees to 20 degrees; and an included angle between a phase difference axis of the ¼λ phase delay layer 23 and the transmission axis of the linear polarizer 3 may be 70 degrees to 80 degrees.

In implementations provided by the embodiments of the present disclosure, the included angle between the phase difference axis of the ½λ phase delay layer 22 and the transmission axis of the linear polarizer 3 may be 15 degrees; and the included angle between the phase difference axis of the ¼λ phase delay layer 23 and the transmission axis of the linear polarizer 3 may be 75 degrees. In such a case, the touch substrate layer 2 cooperates with the linear polarizer 3, which can achieve the accurate effect of circularly polarized light, and the anti-reflection effect is the best.

In implementations provided by the embodiments of the present disclosure, the ½λ phase delay layer 22 and the ¼λ phase delay layer 23 may be made of the same material.

For example, in the touch substrate layer 2, the ½λ phase delay layer and the ¼λ phase delay layer may be both made of the cycloolefin copolymer (COP) material, or may be both made of the polyethylene terephthalate (PET) material, or may be both made of the polycarbonate (PC) material.

In implementations provided by the embodiments of the present disclosure, the ½λ phase delay layer 22 and the ¼λ phase delay layer 23 may be made of different materials.

For example, the ½λ phase delay layer is made of the cycloolefin copolymer (COP) material, and the ¼λ phase delay layer is made of the polyethylene terephthalate (PET) material or the polycarbonate (PC) material. Alternatively, the ¼λ phase delay layer is made of the cycloolefin copolymer (COP) material, and the ½λ phase delay layer is made of the polyethylene terephthalate (PET) material or the polycarbonate (PC) material.

Optionally, in implementations provided by the embodiments of the present disclosure, a phase difference value of the ¼λ phase delay layer in embodiments of the present disclosure may be 110 nm-165 nm, that is, the ¼λ phase delay layer can retard the phase of light waves with a wavelength in the range of 440 nm-660 nm by 110 nm-165 nm. In other words, the ¼λ phase delay layer can retard the phase of visible light by ¼λ.

Optionally, in implementations provided by the embodiments of the present disclosure, a phase difference value of the ½λ phase delay layer in embodiments of the present disclosure may be 220 nm-330 nm, that is, the ½λ phase delay layer can retard the phase of light waves with the wavelength in the range of 440 nm-660 nm by 220 nm-330 nm. In other words, the ½λ phase delay layer can retard the phase of the visible light by ½λ.

Since the above ¼λ phase delay layer and the ½λ phase delay layer both can act on the visible light, the effect of preventing the reflection of the ambient light can be well achieved after cooperating with the linear polarizer 3.

As shown in FIG. 1 and FIG. 2, in the OLED display panel provided by the embodiments of the present disclosure, the OLED display substrate 1, the touch substrate 5 and the linear polarizer 3 may be bonded together in sequence through transparent adhesive layers.

As shown in FIG. 1 and FIG. 2, the touch electrode 4 in the touch substrate 5 is provided on a side, facing the linear polarizer 3, of the touch substrate layer 2.

Based on the same inventive concept, embodiments of the present disclosure further provide a display device. The display device includes the display panel as described by any one of the above. The implementation of the display device may refer to the embodiments of the above display panel, and the repetition is not repeated here.

The display device provided by the embodiments of the present disclosure is an OLED display device. Compared with a conventional OLED display device, the OLED display device provided by the embodiments of the present disclosure has a lower cost, a thinner thickness, a lower reflectivity, a higher contrast, and a better integrated black effect.

The OLED display device provided by the embodiments of the present disclosure may be a display, a notebook computer, a tablet computer, a smart phone and other products.

Obviously, those skilled in the art can make various changes and modifications to the embodiments of the present disclosure without departing from the spirit and scope of the present disclosure. Thus, if these modifications and variations of the present disclosure fall within the scope of the claims of the present disclosure and their equivalents, the present disclosure is also intended to include these modifications and variations.

1. A display panel, comprising:
an OLED display substrate;
a touch substrate, located on a display surface of the OLED display substrate, and comprising:
a touch substrate layer configured as a phase delay layer; and
a touch electrode on a side, facing away from the OLED display substrate, of the touch substrate layer; and
a linear polarizer on a side, away from the OLED display substrate, of the touch substrate, wherein the linear polarizer cooperates with the touch substrate layer to reduce a reflection effect of the display panel on ambient light.

2. The display panel according to claim 1, wherein the touch substrate layer is a ¼λ phase delay layer, and an included angle between a phase difference axis of the ¼λ phase delay layer and a transmission axis of the linear polarizer ranges from 40 degrees to 50 degrees.

3. The display panel according to claim 2, wherein the included angle between the phase difference axis of the ¼λ phase delay layer and the transmission axis of the linear polarizer is 45 degrees.

4. The display panel according to claim 1, wherein the touch substrate layer comprises:
a ½λ phase delay layer; and
a ¼λ phase delay layer;
wherein the ½λ phase delay layer is closer to the linear polarizer than the ¼λ phase delay layer;
an included angle between a phase difference axis of the ½λ phase delay layer and a transmission axis of the linear polarizer ranges from 10 degrees to 20 degrees; and
an included angle between a phase difference axis of the ¼λ phase delay layer and the transmission axis of the linear polarizer ranges from 70 degrees to 80 degrees.

5. The display panel according to claim 4, wherein:
the included angle between the phase difference axis of the ½λ phase delay layer and the transmission axis of the linear polarizer is 15 degrees; and
the included angle between the phase difference axis of the ¼λ phase delay layer and the transmission axis of the linear polarizer is 75 degrees.

6. The display panel according to claim 4, wherein:
the ½λ phase delay layer and the ¼λ phase delay layer are made of a same material.

7. The display panel according to claim 1, wherein a material of the touch substrate layer comprises one or more of:
cycloolefin copolymer,
polyethylene terephthalate, or
polycarbonate.

8. The display panel according to claim 2, wherein a phase difference value of the ¼λ phase delay layer is 110 nm-165 nm.

9. The display panel according to claim 4, wherein a phase difference value of the ½λ phase delay layer is 220 nm-330 nm.

10. A display device, comprising the display panel according claim 1.

11. The display panel according to claim 4, wherein:
the ½λ phase delay layer and the ¼λ phase delay layer are made of different materials.

12. The display panel according to claim 4, wherein a phase difference value of the ¼λ phase delay layer is 110 nm-165 nm.
